(19) United States
(12) Patent Application Publication
(10) Pub. No.: US 2026/0031137 A1
(43) Pub. Date: Jan. 29, 2026

(54) MEMORY DEVICE AND MEMORY SYSTEM INCLUDING THEREOF

(71) Applicant: SAMSUNG ELECTRONICS CO., LTD., Suwon-si (KR)

(72) Inventors: Chinam KIM, Suwon-si (KR); Kwangsu KIM, Suwon-si (KR); Do-Han KIM, Suwon-si (KR); Youngjae PARK, Suwon-si (KR); Jongmin PARK, Suwon-si (KR); Changmin LEE, Suwon-si (KR)

(73) Assignee: SAMSUNG ELECTRONICS CO., LTD., Suwon-si (KR)

(21) Appl. No.: 19/081,782

(22) Filed: Mar. 17, 2025

(30) Foreign Application Priority Data
Jul. 25, 2024 (KR) 10-2024-0098561
Oct. 24, 2024 (KR) 10-2024-0146574

(51) Int. Cl. G11C 11/4093

(52) U.S. Cl. CPC G11C 11/4093

(57) ABSTRACT

Disclosed is a memory device communicating with a host device. The memory device may comprise a plurality of memory banks, a mode register array including a plurality of mode registers, a first mode register buffer, including a first plurality of buffer bit fields, configured to load raw data provided from a target mode register, which is one of the plurality of mode registers, to the first plurality of buffer bit fields in response to a first command received from the host device, and an input/output circuit configured to output one or more target bits stored in the first plurality of buffer bit fields to the host device in response to a second command received from the host device.

### CROSS-REFERENCE TO RELATED APPLICATION

This application claims priority to and the benefit of Korean Patent Application No. 10-2024-0098561 filed in the Korean Intellectual Property Office on Jul. 25, 2024, and Korean Patent Application No. 10-2024-0146574 filed in the Korean Intellectual Property Office on Oct. 24, 2024, the entire contents of which are incorporated herein by reference.

### BACKGROUND OF THE INVENTION

### (a) Field of the Invention

The present disclosure relates to a semiconductor memory device. More specifically, the present disclosure relates to a semiconductor memory device including a mode register, and a memory system including the same.

### (b) Description of the Related Art

A memory device may include a plurality of mode registers. Each of the plurality of mode registers may store different types of information required for operation of a memory device, or may store different types of information indicating a state of the memory device. A host device may set the operation of the memory device or read state information of the memory device by accessing to the mode registers.

The channel used by the host device to access the mode register may be the same as the channel used for normal input/output operations of the memory device. For example, data to be stored in the mode register during a mode register write operation or data read from the mode register during a mode register read operation may be transmitted through a channel used for input/output operations to a memory bank in the memory device. Therefore, input/output operations for the memory bank may be delayed due to the host device accessing the mode registers.

### SUMMARY

The present disclosure attempts to provide a memory device with reduced input/output delays caused by access to a mode register, and a memory system including the same.

An embodiment of the present disclosure provides a memory device communicating with a host device, the memory device comprising: a plurality of memory banks; a mode register array including a plurality of mode registers; a first mode register buffer, including a first plurality of buffer bit fields, configured to load raw data provided from a target mode register, which is one of the plurality of mode registers, to the first plurality of buffer bit fields in response to a first command received from the host device; and an input/output circuit configured to output one or more target bits stored in the first plurality of buffer bit fields to the host device in response to a second command received from the host device.

Another embodiment of the present disclosure provides a memory system comprising: a memory device including: a mode register buffer including a plurality of buffer bit fields and a mode register array including a plurality of mode registers; and a host device configure to: load, into the plurality of buffer bit fields, a raw data stored in a first target mode register, which is one of the plurality of mode registers, by issuing a first command; and read at least a part of the plurality of buffer bit fields by issuing a second command.

Still another embodiment of the present disclosure provides a memory device comprising: a plurality of memory banks; a mode register array including a plurality of mode registers; an input/output circuit configured to communicate with an external device; and a mode register buffer, connected between the mode register array and the input/output circuit, configured to buffer input/output for one of the plurality of mode registers.

### BRIEF DESCRIPTION OF THE DRAWINGS

FIG. 1 is a block diagram illustrating a memory system according to an embodiment of the present disclosure.

FIG. 2 is a block diagram illustrating a memory device of FIG. 1 in more detail.

FIG. 3 is a diagram illustrating an operation of the memory device of FIG. 2 according to a command issued from a host device.

FIG. 4 is a diagram illustrating the operation of the memory device of FIG. 3 in response to a multi-location read command in more detail.

FIG. 5 is a timing diagram illustrating the operation of the memory device according to an embodiment.

FIG. 6 is a diagram illustrating the operation of the memory device of FIG. 3 in response to a multi-location write command in more detail.

FIG. 7 is a timing diagram illustrating the operation of the memory device according to an embodiment.

FIG. 8 is a diagram illustrating an exemplary configuration of a data bundle according to an embodiment.

FIG. 9 is a diagram illustrating an exemplary configuration of a mode register buffer management table of FIG. 1.

FIG. 10 is a graph illustrating the effect of accessing the mode register according to an embodiment of the present disclosure.

FIG. 11 is a flowchart illustrating the operation of the memory system according to an embodiment.

FIG. 12 is a flowchart illustrating the operation of the memory system according to an embodiment.

FIG. 13 is a timing diagram illustrating the operation of the memory device according to an embodiment.

FIG. 14 is a diagram illustrating an exemplary configuration of a third data bundle of FIG. 13.

FIG. 15 is a diagram illustrating a configuration of the memory device according to an embodiment.

FIG. 16 is a diagram illustrating an exemplary configuration of the mode register buffer management table of FIG. 1 according to an embodiment.

### DETAILED DESCRIPTION OF THE EMBODIMENTS

In the following detailed description, only certain embodiments of the present invention have been illustrated and described, simply by way of illustration. Details, such as specific configurations and structures, are provided simply to provide a general understanding of embodiments of the present disclosure. Therefore, variations of embodiments described herein may be performed by those skilled in the art without departing from the technical spirit and scope of the present disclosure. Furthermore, descriptions of well-known features and structures are omitted for clarity and brevity. The configurations in the following drawings or detailed description may be associated with components other than those illustrated in the drawings or described in the detailed description. As used herein, the terms are defined in light of the features of the present disclosure and are not limited to any particular feature. The definitions of terms may be determined based on what is described in the detailed description.

The components described by referencing to terms, such as driver or block as used in the detailed description may be implemented in software, hardware, or a combination thereof. For example, software may be machine code, firmware, embedded code, and application software. For example, the hardware may include electrical circuits, electronic circuits, processors, computers, integrated circuit cores, pressure sensors, inertial sensors, micro-electro mechanical systems (MEMS), passive devices, or combinations thereof.

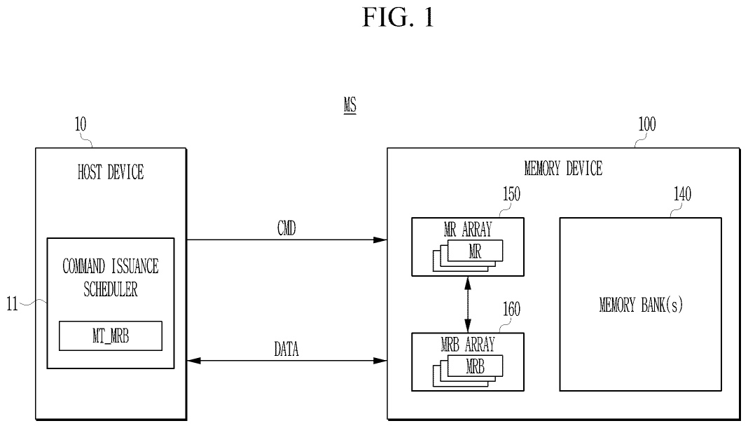

FIG. 1 is a block diagram illustrating a communication system according to an embodiment of the present disclosure. Referring to FIG. 1, a memory system MS may include a host device 10 and a memory device 100.

The host device 10 may control the memory device 100 by issuing various types of commands CMD. For example, the host device 10 may issue read commands to read data from the memory device 100, or may issue write commands to store data in the memory device 100.

In an embodiment, the host device 10 may issue various types of commands CMD in a form of command/address signals C/A.

In an embodiment, the host device 10 may be included in one of various types of processors, such as a central processing unit (CPU), and a graphics processing unit (GPU).

The memory device 100 may include one or more memory banks 140. Each memory bank 140 may store data. For example, each memory bank 140 may include a plurality of memory cells.

The memory device 100 may include a mode register (MR) array 150.

The mode register array 150 may include one or more mode registers MR. Each of the one or more mode registers MR may be implemented to store a predetermined type of information. For example, each mode register MR may store information required for the operation of the memory device 100, or may store information indicating the state of the memory device 100.

In the following, for the concise description, it is assumed that the memory device 100 is a dynamic random access memory (DRAM), and that the host device 10 and the memory device 100 communicate with each other based on a double data rate (DDR) interface. However, the scope of the present disclosure is not limited thereto, and the technical spirit of the present disclosure may be applied to any type of memory device that includes mode registers MR. For example, the host device 10 and the memory device 100 may communicate with each other based on a low power double data rate (LPDDR) interface.

In an embodiment, the host device 10 may set the mode registers MR by issuing a mode register write command. For example, the host device 10 may issue a mode register write command to store information in a mode register MR. However, the scope of the present disclosure is not limited thereto. For example, the host device 10 may be implemented to store information in two or more mode registers MR, or to store information in some bit fields included in one mode register MR, by issuing a mode register write command.

In an embodiment, the host device 10 may read data stored in the mode registers MR by issuing a mode register read command. For example, the host device 10 may issue a mode register read command to store information in one mode register MR. However, the scope of the present disclosure is not limited thereto. For example, the host device 10 may be implemented to read information stored in two or more mode registers MR, or to read information in some bit fields included in one mode register MR, by issuing a mode register read command.

In an embodiment, the host device 10 may need to access a specific mode registers MR frequently. For example, the host device 10 may identify a state of the memory device 100 by frequently accessing a mode register MR which indicating the state information of the memory device 100, such as temperature, operating voltage, whether a row hammering threat has occurred, whether additional refresh operation is required. And, the host device 10 may maintain operational stability of the memory device 100 based on the state of the memory device 100.

In an embodiment, the host device 10 may use same channels for input/output operations of the memory bank 140 and for accessing to the mode register array 150. For example, the host device 10 may access the memory bank 140 and the mode register array 150 based on same data bus. Thus, while the host device 10 is accessing a specific mode register MR, the host device 10 may not be able to perform input/output operations to the memory bank 140. In other words, due to the access of the host device 10 to the mode register array 150, the host device 10 should delay performing input/output operations to the memory bank 140. In particular, when the host device 10 accesses a specific mode register MR with high frequency, the performance of input/output operations to the memory bank 140 of the host device 10 may be significantly deteriorated.

The memory device 100 may include a mode register buffer (MRB) array 160.

The mode register buffer array 160 may include one or more mode register buffers MRB. Each of one or more mode register buffers MRB may buffer input/output between the host device 10 and the mode registers MR. For example, each mode register buffer MRB may temporarily store (e.g., load or copy) data stored in the mode register MR, and then output the temporarily stored data in response to a request from the host device 10; or temporarily store data to be stored in the mode register MR provided from the host device 10 and then flush the temporarily stored data into a specific mode register MR in response to a request from the host device 10. That is, according to an embodiment of the present disclosure, the host device 10 may access the mode register array 150 via the mode register buffer array 160.

The data movement between the mode register buffer array 160 and the mode register array 150 may be independent from the channel (e.g., data bus) used for input/output operations to the memory bank 140 of the host device 10. That is, the data movement between the mode register buffer array 160 and the mode register array 150 may be performed even while the host device 10 is accessing the memory bank 140. In other words, the data movement between the mode register buffer array 160 and the mode register array 150 may not delay the input/output operations to the memory bank 140 of the host device 10.

The data movement between the mode register buffer array 160 and the host device 10 may be performed in a unit small enough not to delay input/output operations to the memory bank 140 of the host device 10. For example, the data movement between the mode register buffer array 160 and the host device 10 may be performed in a unit smaller than or equal to the capacity of one mode register MR. However, the scope of the present disclosure is not limited thereto.

In an embodiment, a form factor used for data communication between the host device 10 and the memory device 100 may be implemented to support a “wide-NRZ” scheme. For example, a unit of data communication between the host device 10 and the memory device 100 may be implemented to include a bank data and an auxiliary data. In this case, the data movement between the mode register buffer array 160 and the host device 10 may be performed in a form of the auxiliary data. That is, the data movement between the mode register buffer array 160 and the host device 10 may be processed together when bank data movement between the host device 10 and the memory device 100 is performed. Thus, according to an embodiment of the present disclosure, degradation of the performance of input/output operations to the memory bank 140 may be prevented even when the channel used for communication between the mode register buffer array 160 and the host device 10 is same as the channel used for input/output operations to the memory bank 140 of the host device 10.

The host device 10 may include a command issuance scheduler 11. The command issuance scheduler 11 may include a mode register buffer management table MT_MRB. The mode register buffer management table MT_MRB may indicate a state of data stored in each of the mode register buffers MRB included in the mode register buffer array 160.

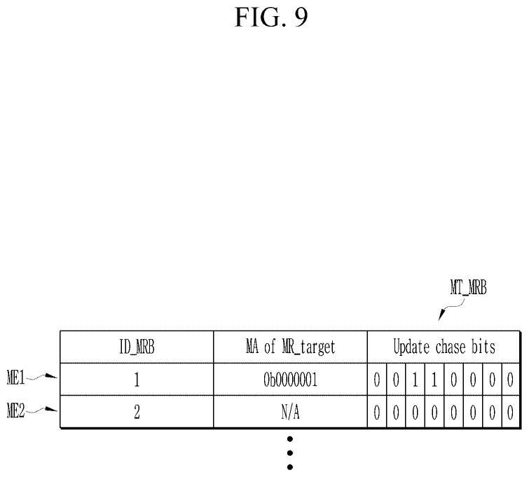

The command issuance scheduler 11 may issue various types of commands for accessing the mode register MR based on the mode register buffer management table MT_MRB. For example, the command issuance scheduler 11 may determine, based on the mode register buffer management table MT_MRB, the order of issuance and a time point of issuance of one or more commands CMD for accessing to the mode register MR. The configuration of the mode register buffer management table MT_MRB and the operation of the command issuance scheduler 11 will be described in more detail with reference to FIG. 9 below.

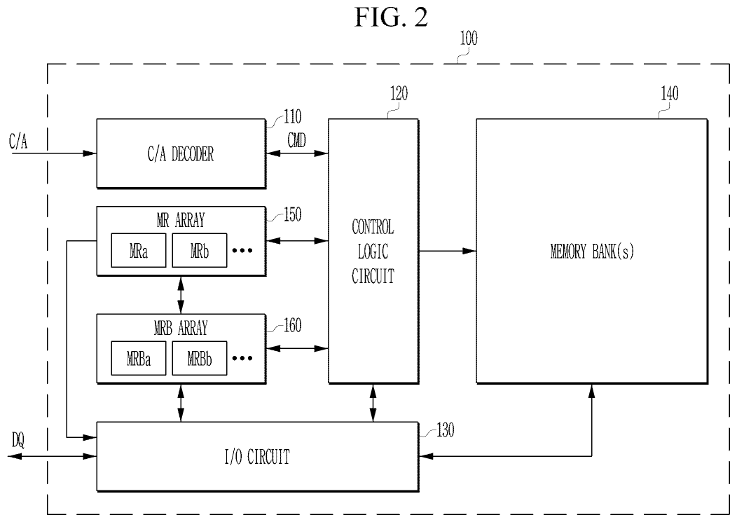

FIG. 2 is a block diagram illustrating the memory device of FIG. 1 in more detail. Referring to FIG. 2, the memory device 100 may include a command/address decoder 110, a control logic circuit 120, one or more memory banks 140, an input/output circuit 130, a mode register array 150, and a mode register buffer array 160.

The command/address decoder 110 may receive command/address signals C/A provided by the host device 10. The command/address decoder 110 may decode the command/address signals C/A into commands CMD. That is, the command/address decoder 110 may receive commands CMD from the host device 10 in a form of command/address signals C/A.

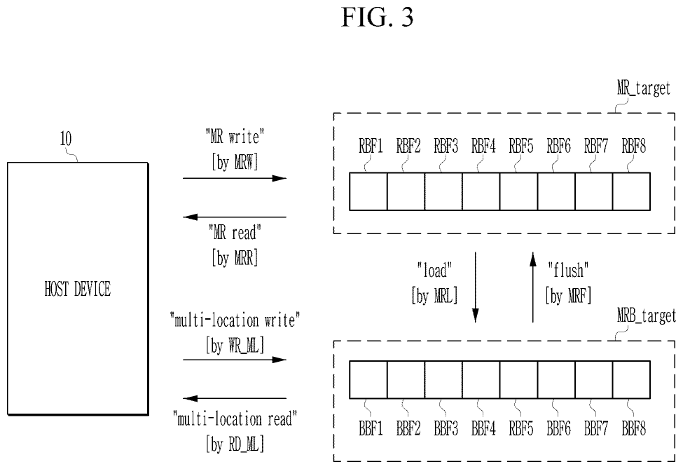

The commands CMD may include various types of commands, such as an active command, a precharge command, a read command, a write command, a mode register read command, a mode register write command, a mode register load command, a mode register flush command, a multi-location read command, and a multi-location write command. The operation of the memory device 100 based on the type of command CMD will be described in more detail with reference to FIG. 3 below.

The control logic circuit 120 may receive a command CMD. The control logic circuit 120 may control various operations of the memory device 100 based on the command CMD. For example, the control logic circuit 120 may control the operations of the one or more memory banks 140, the mode register array 150, the mode register buffer array 160, and the input/output circuit 130 based on the command CMD.

The input/output circuit 130 may communicate with the host device 10 in a form of data signals DQ. For example, the input/output circuit 130 may receive data DATA in a form of a data signals DQ from the host device 10, or may transmit data DATA to the host device 10 in a form of data signals DQ.

Each of the one or more memory banks 140 may include a plurality of memory cells. In response to control from the control logic circuit 120, each of the one or more memory banks 140 may store data DATA in a plurality of memory cells and/or output data DATA stored in the plurality of memory cells.

The mode register array 150 may include one or more mode registers MR. For example, the mode register array 150 may include a first mode register MRa and a second mode register MRb. However, the scope of the present disclosure is not limited to the number of mode registers MR included in the mode register array 150.

The mode register buffer array 160 may be connected between the mode register array 150 and the input/output circuit 130. The mode register buffer array 160 may include one or more mode register buffers MRB. For example, the mode register buffer array 160 may include a first mode register buffer MRBa and a second mode register buffer MRBb. However, the scope of the present disclosure is not limited to the number of mode register buffers MRB included in the mode register buffer array 160.

In response to control of the control logic circuit 120, the input/output circuit 130 may store data DATA provided by the host device 10 in the memory bank 140, and may provide the data DATA provided by the memory bank 140 to the host device 10.

In an embodiment, the data DATA transmitted by the input/output circuit 130 to the memory bank 140, and the data DATA provided to the input/output circuit 130 from the memory bank 140 may be referred to as bank data D_BNK.

In response to control of the control logic circuit 120, the input/output circuit 130 may store the data DATA provided from the host device 10 in the mode register array 150, and may provide the data DATA provided from the mode register array 150 to the host device 10.

In an embodiment, the data DATA transmitted by the input/output circuit 130 to the mode register array 150, and the data DATA provided to the input/output circuit 130 from the mode register array 150, may be referred to as mode register data D_MR.

The mode register buffer array 160 may buffer data transmission between the input/output circuit 130 and the mode register array 150. For example, the input/output circuit 130 may provide the mode register data D_MR to the mode register array 150 via the mode register buffer array 160, and the mode register array 150 may provide the mode register data D_MR to the input/output circuit 130 via the mode register buffer array 160. In other words, the mode register buffer array 160 may buffer input/output to the mode register array 150 of the host device 10. The specific manner in which the mode register buffer array 160 buffers the mode register data D_MR will be described in more detail below with reference to FIGS. 3 to 12.

In an embodiment, the input/output circuit 130 may also directly exchange the mode register data D_MR with the mode register array 150 (e.g., without going through the mode register buffer array 160).

FIG. 3 is a diagram illustrating an operation of the memory device of FIG. 2 according to a command issued from the host device. Referring now to FIGS. 1 to 3, an embodiment in which the host device 10 issues commands CMD for one mode register MR and one mode register buffer MRB will be described representatively. For example, it is assumed herein that the host device 10 issues the command CMD for a target mode register MR_target and a target mode register buffer MRB_target. In this case, the target mode register MR_target may be a mode register MR included in the mode register array 150, and the target mode register buffer MRB_target may be a mode register buffer MRB included in the mode register array 150. However, the scope of the present disclosure is not limited thereto.

The target mode register MR_target may include a plurality of register bit fields RBF. For example, the target mode register MR_target may include first to eighth register bit fields RBF1 to RBF8. Herein after, for concise description, an embodiment in which the target mode register MR_target is implemented as an 8-bit register is described below representatively. However, the scope of the present disclosure is not limited to the capacity of the target mode register MR_target.

The target mode register buffer MRB_target may include a plurality of buffer bit fields BBF. For example, the target mode register buffer MRB_target may include first to eighth buffer bit fields BBF1 to BBF8. Herein after, for concise description, an embodiment in which the target mode register buffer MRB_target is implemented with the same capacity as the target mode register MR_target is described representatively. However, the scope of the present disclosure is not limited to the capacity of the target mode register buffer MR_target.

The host device 10 may perform a mode register write operation to the target mode register MR_target by issuing a mode register write command MRW. For example, the input/output circuit 130 may receive mode register data D_MR to be stored in the target mode register MR_target, from the host device 10. The control logic circuit 120 may identify the target mode register MR_target based on the mode register address included in the mode register write command MRW. The input/output circuit 130 may write the mode register data D_MR to the target mode register MR_target in response to control of the control logic circuit 120.

In an embodiment, the capacity of the mode register data D_MR which is written to the target mode register MR_target in response to the mode register write command MRW may be same as the capacity of the target mode register MR_target. For example, the host device 10 may provide an 8-bit size of the mode register data D_MR to the memory device 100 along with the mode register write command MRW. That is, the host device 10 may update all register bit fields RBF of the target mode register MR_target based on the mode register write command MRW.

The host device 10 may perform a mode register read operation to the target mode register MR_target by issuing a mode register read command MRR. For example, the control logic circuit 120 may identify the target mode register MR_target based on a mode register address included in the mode register read command MRR. In response to control of the control logic circuit 120, the input/output circuit 130 may read the mode register data D_MR from the target mode register MR_target, and may provide the read mode register data D_MR to the host device 10.

In an embodiment, the capacity of the mode register data D_MR which is read out of the target mode register MR_target in response to the mode register read command MRR may be same as the capacity of the target mode register MR_target. For example, the memory device 100 may provide an 8-bit sized mode register data D_MR to the host device 10 in response to the mode register read command MRR. That is, the host device 10 may read out all of the register bit fields RBF of the target mode register MR_target based on the mode register read command MRR.

The host device 10 may load data stored in the target mode register MR_target into the target mode register buffer MRB_target by issuing a mode register load command MRL. For example, the control logic circuit 120 may identify the target mode register MR_target based on a mode register address included in the mode register load command MRL, and may identify the target mode register buffer MRB_target based on a mode register buffer identifier (hereinafter referred to as “ID_MRB”) included in the mode register load command MRL. The target mode register buffer MRB_target may load data stored in the target mode register MR_target in response to control from the control logic circuit 120. In this case, the first to eighth buffer bit fields BBF1 to BBF8 may load bits of the first to eighth register bit fields RBF1 to RBF8, respectively.

That is, the host device 10 may synchronize the target mode register buffer MRB_target with the target mode register MR_target by issuing the mode register load command MRL.

In an embodiment, the memory device 100 may load part of the target mode register MR_target into the target mode register buffer MRB_target in response to the mode register load command MRL. In this case, the mode register load command MRL may further include information about register bit fields from among the plurality of register bit fields RBF, which is to be loaded into the target mode register buffer MRB_target. However, for more concise description, it is assumed herein that the memory device 100 loads the entire target mode register MR_target into the target mode register buffer MRB_target in response to the mode register load command MRL.

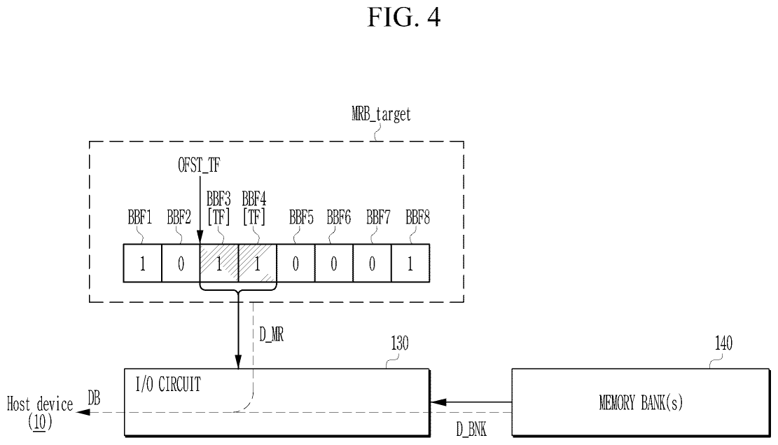

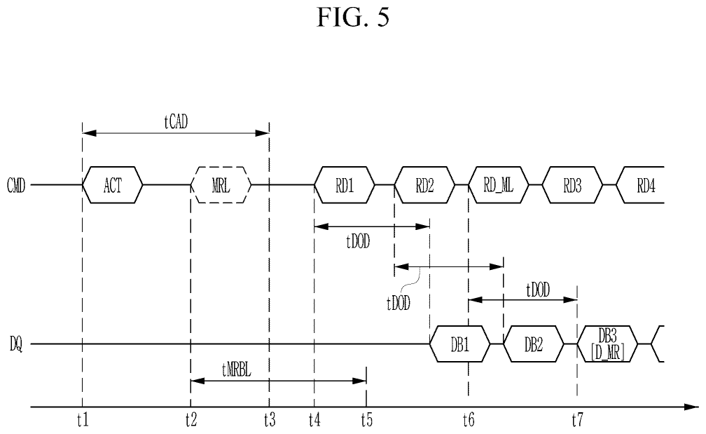

The host device 10 may read all or a part of the target mode register buffer MRB_target by issuing a multi-location read command RD_ML. For example, the control logic circuit 120 may identify the target mode register buffer MRB_target based on a mode register buffer identifier ID_MRB included in the multi-location read command RD_ML. In response to control from the control logic circuit 120, the input/output circuit 130 may provide some or all of the bits stored in the target mode register buffer MRB_target to the host device 10 as mode register data D_MR. For example, the input/output circuit 130 may provide bits stored in some or all of the bit fields of the first to eighth buffer bit fields BBF1 to BBF8 to the host device 10. The operation of the memory device 100 in response to the multi-location read command RD_ML will be described in more detail with reference to FIGS. 4 and 5 below.

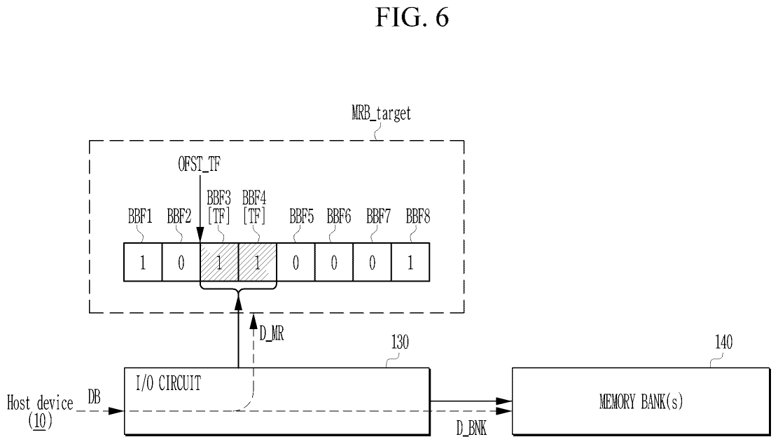

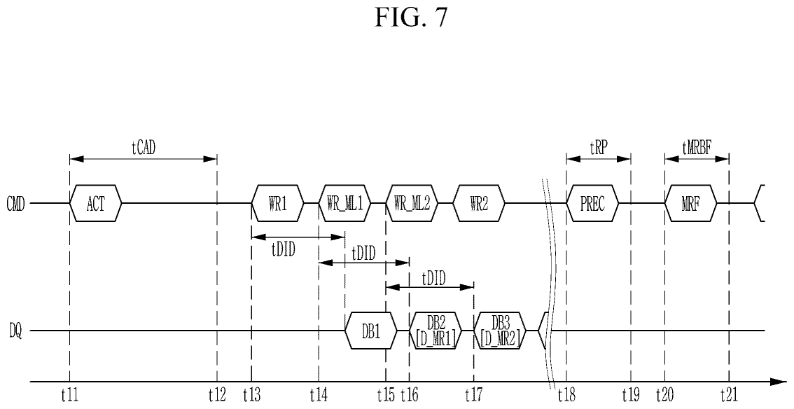

The host device 10 may update all or some of the buffer bit fields BBF of the target mode register buffer MRB_target by issuing a multi-location write command WR_ML. For example, the host device 10 may provide the mode register data D_MR to the memory device 100 together with the multi-location write command WR_ML. The control logic circuit 120 may identify the target mode register buffer MRB_target based on the mode register buffer identifier ID_MRB included in the multi-location write command WR_ML. In response to control from the control logic circuit 120, the input/output circuit 130 may update all or some of the buffer bit fields BBF of the target mode register buffer MRB_target based on the mode register data D_MR. For example, the input/output circuit 130 may update some or all of the first to eighth buffer bit fields BBF1 to BBF8 based on the mode register data D_MR provided from the host device 10. The operation of the memory device 100 in response to the multi-location write command WR_ML will be described in more detail with reference to FIGS. 6 and 7 below.

The host device 10 may flush data stored in the target mode register buffer MRB_target to the target mode register MR_target by issuing a mode register flush command MRF. For example, the control logic circuit 120 may identify the target mode register MR_target based on a mode register address included in the mode register flush command MRF, and may identify the target mode register buffer MRB_target based on a mode register buffer identifier ID_MRB included in the mode register flush command MRF. The control logic circuit 120 may update the first to eighth register bit fields RBF1 to RBF8 based on the first to eighth buffer bit fields BBF1 to BBF8, respectively.

That is, the host device 10 may synchronize the target mode register MR_target with the target mode register buffer MRB_target by issuing the mode register flush command MRF.

In an embodiment, the memory device 100 may flush a part of the plurality of buffer bit fields BBF into the target mode register MR_target in response to the mode register flush command MRF. In this case, the mode register flush command MRF may further include information about which of the plurality of buffer bit fields BBF to be flushed to the target mode register MR_target. However, for more concise description, it is assumed herein that the memory device 100 flushes the entire target mode register buffer MRB_target into the target mode register MR_target in response to the mode register flush command MRF.

In an embodiment, the number of mode register buffers MRB included in the mode register buffer array 160 may be one. In this case, the mode register load command MRL, the multi-location read command RD_ML, the multi-location write command WR_ML, and the mode register flush command MRF may not include the mode register buffer identifier ID_MRB.

In an embodiment, the number of mode register buffers MRB included in the mode register buffer array 160 may be the same as the number of mode registers MR included in the mode register array 150. In this case, the mode register load command MRL and the mode register flush command MRF may not include the mode register address representing the target mode register MR_target.

FIG. 4 is a diagram illustrating the operation of the memory device of FIG. 3 in response to a multi-location read command in more detail. Referring to FIGS. 1 to 4, the host device 10 may issue a multi-location read command RD_ML.

The multi-location read command RD_ML may include a bank address and a column address for one memory bank 140.

The memory device 100 may perform a read operation to the one memory bank 140 based on the bank address and column address included in the multi-location read command RD_ML. In this case, the corresponding memory bank 140 may provide a bank data D_BNK to the input/output circuit 130.

The multi-location read command RD_ML may include a mode register buffer identifier ID_MRB and a target field offset OFST_TF indicating the location of the bits to be read from the target mode register buffer MRB_target.

The control logic circuit 120 may identify one or more target fields TF of the plurality of buffer bit fields BBF based on the target field offset OFST_TF. For example, when the target field offset OFST_TF is ‘3’, the control logic circuit 120 may determine the third buffer bit field BBF3 and one buffer bit field adjacent to the third buffer bit field BBF3 (e.g., the fourth buffer bit field BBF4) as target fields TF. However, the scope of the present disclosure is not limited to the specific algorithm by which the control logic circuit 120 identifies the target field TF based on the target field offset OFST_TF.

In an embodiment, the number of buffer bit fields BBF of the plurality of buffer bit fields BBF that the control logic circuit 120 identifies as the target field TF may be predetermined. For example, the control logic circuit 120 may identify two buffer bit fields among the plurality of buffer bit fields BBF as target fields TF. However, the scope of the present disclosure is not limited to the predetermined number of target fields TF.

The target mode register buffer MRB_target may, in response to control from the control logic circuit 120, provide the input/output circuit 130 with mode register data D_MR including bits (which may be referred to herein as “target bits”) stored in one or more target fields TF.

In other words, the input/output circuit 130 may receive the bank data D_BNK and the mode register data D_MR based on a single multi-location read command RD_ML.

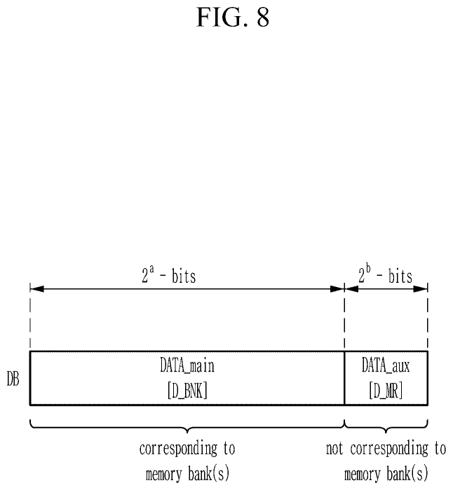

The input/output circuit 130 may output the bank data D_BNK and the mode register data D_MR to the host device 10. For example, the input/output circuit 130 may provide the host device 10 with a data bundle DB including the bank data D_BNK and the mode register data D_MR, in response to the multi-location read command RD_ML. In other words, the host device 10 may read the bank data D_BNK and the mode register data D_MR simultaneously by issuing the multi-location read command RD_ML. The configuration of the data bundle DB will be described in more detail with reference to FIG. 8 below.

FIG. 5 is a timing diagram illustrating the operation of the memory device according to an embodiment. Referring to FIGS. 1 to 5, at a first time point t1, the host device 10 may issue an activation command ACT. The activation command ACT may include a bank address and a row address for the memory bank 140.

From a first time point t1 to a third time point t3 after the column access delay time tCAD has elapsed from the first time point t1, the host device 10 may be prohibited from issuing the read commands RD and the multi-location read command RD_ML. That is, the host device 10 may only issue the read command RD or the multi-location read command RD_ML as follow-up commands for the activation command ACT after the third time point t3.

In an embodiment, the column access delay time tCAD may indicate a time taken for data for one memory cell row to be stored in a sense amplification circuit within the memory bank 140.

On the other hand, because the mode register load command MRL only causes data movement between the mode register array 150 and the mode register buffer array 160, the mode register load command MRL may be processed independently to the operation of the memory bank 140. Thus, the host device 10 may issue the mode register load command MRL regardless of (e.g., independent of) the column access delay time tCAD. Further, the host device 10 may issue the mode register load command MRL independently of the state of each of the memory banks 140. For example, the host device 10 may issue the mode register load command MRL not only in case of all of the one or more memory banks 140 are in a precharged state, but also in case of some of the memory banks 140 are in an activated state. In a more detailed example, the host device 10 may issue the register load command MRL at a second time point t2 between the first time point t1 and the third time point t3.

The memory device 100 may load (e.g., store) raw data (e.g., mode register bits) from the target mode register MR_target into the target mode register buffer MRB_target in response to the mode register load command MRL. For example, from the second time point t2 to the fifth time point t5 after a mode register buffer load time tMRBL has elapsed from the second time point t2, access for the target mode register buffer MRB_target by the host device 10 may be prohibited. That is, the host device 10 may be allowed to issue the multi-location read command RD_ML only after the fifth time point t5.

For more concise description, the order of the second to fifth time point t2 to t5 is illustrated in FIG. 5 as sequentially, but the scope of the present disclosure is not limited thereto. For example, according to a time point when the host device 10 issues the mode register load command MRL, the order of the second to fifth time points t2 to t5 may be varied.

After the third time point t3, the host device 10 may issue a plurality of read commands RD sequentially. For example, at the fourth time point t4 after the third time point t3, the host device 10 may issue a first read command RD1. After the data output delay time tDOD has elapsed from the third time point t3, the memory device 100 may output a first data bundle DB1 including a bank data D_BNK corresponding to the first read command RD1. In this case, the first data bundle DB1 may not include a mode register data D_MR (i.e., data provided from the mode register array 150). Similarly, the memory device 100 may receive a second read command RD2 from the host device 10 and output a second data bundle DB2 after the data output delay time tDOD has elapsed from the time point at which the second read command RD2 is received. In this manner, the memory device 100 may sequentially process the plurality of read commands RD received from the host device 10 (e.g., the third and fourth read commands RD3 and RD4).

In an embodiment, the data output delay time tDOD may indicate a time taken for the input/output circuit 130 to generate the data bundle DB in response to the read command RD or a multi-location read command RD_ML from the memory device 100.

After the third time point t3 and the fifth time point t5, the host device 10 may issue a multi-location read command RD_ML. For example, the host device 10 may issue a multi-location read command RD_ML at the sixth time point t6. The memory device 100 may output a third data bundle DB3 including a bank data D_BNK and a mode register data D_MR corresponding to the multi-location read command RD_ML at a seventh time point t7 after the data output delay time tDOD has elapsed from the sixth time point t6.

For more concise description, FIG. 5 illustrates that the time interval between the sixth time point t6 and the seventh time point t7 is the data output delay time tDOD, but the scope of the present disclosure is not limited thereto. For example, the time interval between the sixth time point t6 and the seventh time point t7 may be determined as a “multiple data output delay time” that is longer than the data output delay time tDOD.

In an embodiment, the capacity of a data bundle DB that the memory device 100 outputs in response to the read command RD may be the same as the capacity of a data bundle DB that the memory device 100 outputs in response to the multi-location read command RD_ML. For example, the capacity of the first to third data bundles DB1 to DB3 may be the same as each other. In this case, the time (e.g., the number of clock cycles) that the memory device 100 takes to transmit each of the first to third data bundles DB1 to DB3 may be the same as each other. However, the scope of the present disclosure is not limited thereto.

FIG. 6 is a diagram illustrating the operation of the memory device of FIG. 3 in response to a multi-location write command in more detail. Referring to FIGS. 1 to 6, the host device 10 may provide a multi-location write command WR_ML and a data bundle DB to the memory device 100.

The input/output circuit 130 may receive the data bundle DB from the host device 10. The data bundle DB may include a bank data D_BNK and a mode register data D_MR. In other words, the host device 10 may issue a multi-location write command WR_ML to simultaneously transmit the bank data D_BNK and the mode register data D_MR to the memory device 100. The configuration of the data bundle DB will be described in more detail with reference to FIG. 8 below.

The multi-location write command WR_ML may include a bank address and a column address for one memory bank 140.

The memory device 100 may perform a write operation to the one memory bank 140 based on the bank address and the column address included in the multi-location write command WR_ML. In this case, the memory bank 140 may store the bank data D_BNK provided from the input/output circuit 130 at a location corresponding to the column address.

The multi-location write command WR_ML may include a mode register buffer identifier ID_MRB, and a target field offset OFST_TF indicating the location of the bits to be read from the target mode register buffer MRB_target.

The control logic circuit 120 may identify one or more target fields TF of the plurality of buffer bit fields BBF based on the target field offset OFST_TF. Since the manner in which the control logic circuit 120 identifies the one or more target fields TF based on the target field offset OFST_TF is similar to that previously described with reference to FIG. 4, detailed description will be omitted.

The input/output circuit 130 may store the mode register data D_MR in the one or more target fields TF in response to a control of the control logic circuit 120. For example, the input/output circuit 130 may update bits (e.g., “target bits”) stored in the one or more target fields TF based on the mode register data D_MR.

FIG. 7 is a timing diagram illustrating the operation of the memory device according to an embodiment. Referring to FIGS. 1 to 7, at an eleventh time point t11, the host device 10 may issue an activation command ACT. From the eleventh time point t11 to a twelfth time point t12 after the column access delay time tCAD has elapsed from the eleventh time point t11, the host device 10 may be prohibited from issuing a write command WR and a multi-location write commands WR_ML. Since the activation command ACT and the column access delay time tCAD have been previously described with reference to FIG. 5, a detailed description is omitted.

After the twelfth time point t12, the host device 10 may issue a plurality of write commands WR in sequence. For example, at a thirteenth time point t13 after the twelfth time point t12, the host device 10 may issue a first write command WR1. After the data input delay time tDID from the thirteenth time point t13 has elapsed, the memory device 100 may receive the first data bundle DB1 including the bank data D_BNK corresponding to the first write command WR1. In this case, the first data bundle DB1 may not include the mode register data D_MR (i.e., data to be provided to the mode register array 150). The memory device 100 may process the second write command WR2 provided from the host device 10 in a similar manner.

After the twelfth time point t12, the host device 10 may issue a multi-location write command WR_ML. For example, the host device 10 may issue a first multi-location write command WR_ML1 at a fourteenth time point t14. The memory device 100 may receive the second data bundle DB2 corresponding to the first multi-location write command WR_ML1 at a sixteenth time point t16 after the data input delay time tDID has elapsed from the fourteenth time point t14. In this case, the second data bundle DB2 may include not only the bank data D_BNK, but also the mode register data D_MR (i.e., data to be provided to the mode register array 150 via the mode register buffer array 160). Similarly, the host device 10 may issue the second multi-location write command WR_ML2 at the fifteenth time point t15. The memory device 100 may receive the third data bundle DB3 corresponding to the second multi-location write command WR_ML2 at a seventeenth time point t17 after the data input delay time tDID has elapsed from the fifteenth time point t15. In this case, the third data bundle DB3 may also include mode register data D_MR.

In an embodiment, the data input delay time tDID may indicate a time taken for the memory device 100 to prepare to receive the data bundle DB via the input/output circuit 130 in response to the write command WR or the multi-location write command W_ML.

For more concise description, FIG. 7 illustrates an embodiment in which the host device 10 issues the first write command WR1, the first multi-location write command WR_ML1, the second multi-location write command WR_ML2, and the second write command WR2 in sequence, but the scope of the present disclosure is not limited to the order in which the host device 10 issues the commands. For example, the host device 10 may issue the write command WR and the multi-location write command WR_ML in any order.

That is, according to an embodiment of the present disclosure, the host device 10 may issue the multi-location write command WR_ML instead of the write command WR at a time point when the host device 10 is allowed to issue the write command WR (e.g., after the column access delay time tCAD). In this case, even though the host device 10 transmits the mode register data D_MR to the memory device 100, input/output delay may not occur to the operation of the memory device 100.

For more concise description, FIG. 7 illustrates that the time interval between the fourteenth time point t14 and the sixteenth time point t16 is the data input delay time tDID, but the scope of the present disclosure is not limited thereto. For example, the time interval between the fourteenth time point t14 and the sixteenth time point t16 may be determined as a “multiple data input delay time” that is longer than the data input delay time tDID.

In an embodiment, the capacity of a data bundle DB that the memory device 100 receives in response to the write command WR may be the same as the capacity of a data bundle DB that the memory device 100 receives in response to the multi-location write command WR_ML. For example, the capacity of the first to third data bundles DB1 to DB3 may be same as each other. In this case, the time (e.g., the number of clock cycles) that the memory device 100 takes to transmit each of the first to third data bundles DB1 to DB3 may be the same as each other. However, the scope of the present disclosure is not limited thereto.

The host device 10 may issue a precharge command PREC at an eighteenth time point t18 after the write operation to the memory device 100 is completed. For example, the host device 10 may issue various types of precharge commands PREC, such as all-bank precharge commands, or per-bank precharge commands.

In response to the precharge command PREC, the memory device 100 may make transition for all memory banks 140 to an idle state (e.g., a precharge state). For example, the memory device 100 may perform a precharge operation on the memory banks corresponding to the precharge command PREC during a row precharge time tRP from the eighteenth time point t18.

In an embodiment, the row precharge time tRP may indicate a time that the memory device 100 takes to precharge a specific memory bank BNK.

The host device 10 may issue a mode register flush command MRF when all memory banks 140 are in the idle state. For example, the host device 10 may issue a mode register flush command MRF to the memory device 100 at a twentieth time point t20 after all memory banks 140 have been completely precharged.

In an embodiment, the host device 10 may issue the mode register flush command MRF for a specific mode register MR, independent of the state of each memory bank 140. For example, the host device 10 may issue a mode register flush command MRF for a mode register MR, which includes information unrelated to the operation of the memory banks 140 even when some of the memory banks 140 are not precharged (e.g., prior to a nineteenth time point t19). However, the scope of the present disclosure is not limited thereto.

In response to the mode register flush command MRF, the memory device 100 may update the mode register MR represented by the mode register flush command MRF based on data stored in the mode register buffer array 160. For example, the memory device 100 may flush the data stored in the target mode register buffer MRB_target to the target mode register MR_target from the twelfth time point t20 to a twenty-first time point t21 after the mode register buffer flush time tMRBF has elapsed from the twelfth time point t20. In this case, access to the memory device 100 by the host device 10 may be prohibited during the mode register buffer flush time tMRBF. For example, the host device 10 may issue the activation command ACT only after the twenty-first time point t21.

FIG. 8 is a diagram illustrating an exemplary configuration of the data bundle according to an embodiment. Referring to FIGS. 1 to 8, the host device 10 may read data bundle DB from the memory device 100 by issuing the read command RD or the multi-location read command RD_ML, and may provide the data bundle DB to the memory device 100 by issuing the write command WR or the multi-location write command WR_ML. In the following, configurations of the data bundle DB corresponding to a read command RD, a multi-location read command RD_ML, a write command WR, and a multi-location write command WR_ML will be described.

The data bundle DB may include a main data DATA_main and an auxiliary data DATA_aux. The main data DATA_main may have a large capacity compared to the auxiliary data DATA_aux. For example, the main data DATA_main may include 2ª bits, and the auxiliary data DATA_aux may include 2b bits. In this case, ‘a’ may be an integer greater than ‘b’. As a more detailed example, the main data DATA_main may be 256 bits, and the auxiliary data DATA_aux may be 32 bits. However, the scope of the present disclosure is not limited to the specific capacity of the main data DATA_main and the auxiliary data DATA_aux.

In an embodiment, the capacity of one data bundle DB may be determined based on the number of data pins and burst lengths that the input/output circuit 130 utilizes for communication with the host device 10. For example, the capacity of one data bundle DB may be implemented as 288 bits, which is the product of the number of data pins “12” and the burst length “24”. However, the scope of the present disclosure is not limited thereto.

In an embodiment, the form factor used for data communication between the host device 10 and the memory device 100 may not support the “wide-NRZ” scheme. For example, the number of data pins used by the input/output circuit 130 for communication with the host device 10 may be “8” and the burst length may be “32”. In this case, the data bundle DB may not include the auxiliary data DATA_aux. That is, the data bundle DB corresponding to the read command RD or the write command WR may include only the bank data D_BNK, and the data bundle DB corresponding to the multi-data read command RD_ML or the multi-data write command WR_ML may include the bank data D_BNK and the mode register data D_MR. In this case, the capacity of the data bundle DB corresponding to the read command RD or the write command WR may be smaller than the capacity of the data bundle DB corresponding to the multi-data read command RD_ML or the multi-data write command WR_ML. For example, the input/output circuit 130 may apply a relatively large burst length for transmitting the data bundle DB corresponding to the multi-data read command RD and the multi-data write command WR compared to the burst length used for transmitting the data bundle DB corresponding to the read command RD and the write command WR. In this case, the amount of time spent (e.g., clock cycles) for transmitting the data bundle DB between the input/output circuit 130 and the host device 10 may also vary depending on the type of command CMD corresponding to the data bundle DB. However, the scope of the present disclosure is not limited thereto.

The main data DATA_main may include bank data D_BNK. That is, the main data DATA_main may include data to be stored in the memory bank 140 or data read from the memory bank 140. For example, the main data DATA_main included in the data bundle DB provided by the memory device 100 to the host device 10 in response to the read command RD or the multi-location read command RD_ML may include data read from the memory bank 140. The main data DATA_main included in the data bundle DB that the memory device 100 receives from the host device 10 in response to the write command WR or the multi-location write command WR_ML may include data to be written to the memory bank 140.

The auxiliary data DATA_aux may include various types of data that are not bank data D_BNK. For example, the auxiliary data DATA_aux may include various types of data, such as error detection codes (e.g., cyclic redundancy check (CRC) codes, parity bits, and the likes), metadata, and the likes for the bank data D_BNK included in the main data DATA_main.

The type of data included in the auxiliary data DATA_aux may vary according to the type of command CMD corresponding to the data bundle DB. For example, the auxiliary data DATA_aux included in the data bundle DB corresponding to the multi-location read command RD_ML or the multi-location write command WR_ML may include mode register data D_MR. In a more detailed example, the auxiliary data DATA_aux included in the data bundle DB provided by the memory device 100 to the host device 10 in response to the multi-location read command RD_ML may include data read from the mode register array 150 (more specifically, data read from the mode register array 150 and buffered by the mode register buffer array 160). The auxiliary data DATA_aux included in the data bundle DB that the memory device 100 receives from the host device 10 in response to the multi-location write command WR_ML may include data to be written to the mode register array 150 (more specifically, data to be buffered by the mode register buffer array 160 before being written to the mode register array 150). On the other hand, the auxiliary data DATA_aux included in the data bundle DB corresponding to the read command RD_ML or the write command WR may not include mode register data D_MR.

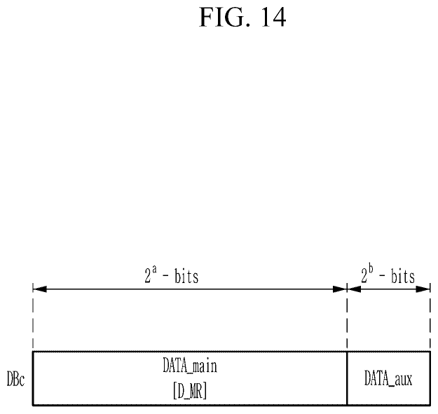

In an embodiment, the data included in the main data DATA_main and auxiliary data DATA_aux may vary according to the type of command CMD corresponding to the data bundle DB. For example, the main data DATA_main of the data bundle DB corresponding to the mode register read command MRR or the mode register write command MRW may not include bank data D_BNK and may include mode register data D_MR only. The configuration of the data bundle DB corresponding to the mode register read command MRR or the mode register write command MRW is described in more detail below with reference to FIG. 14.

FIG. 9 is an exemplary diagram illustrating the configuration of the mode register buffer management table of FIG. 1. The command issuance scheduler 11 may manage the state of each mode register buffer MRB based on the mode register buffer management table MT_MRB.

The mode register buffer management table MT_MRB may include a plurality of management entries ME. For example, the mode register buffer management table MT_MRB may include a first management entry ME1 and a second management entry ME2. The command issuance scheduler 11 may manage the state of the mode register buffer MRB (e.g., the first mode register buffer MRBa) corresponding to the mode register buffer identifier ID_MRB ‘1’ based on the first management entry ME1; and may manage the state of the mode register buffer MRB (e.g., the second mode register buffer MRBb) corresponding to the mode register buffer identifier ID_MRB ‘2’ based on the second management entry ME2.

Each of the plurality of management entries ME may include a mode register address MA indicating a target mode register MR_target corresponding to the mode register buffer MRB.

For example, the host device 10 may load raw data stored in the first mode register MRa into the first mode register buffer MRBa by issuing a mode register load command MRL. In this case, the command issuance scheduler 11 may update the first management entry ME1 based on the mode register address MA of the first mode register MRa (e.g., ‘0b00000001’) so as to indicate that the source of the bits stored in the first mode register buffer MRBa is the first mode register MRa.

On the other hand, the host device 10 may write data into some buffer bit fields BBF of the second mode register buffer MRBb by issuing one or more multi-location write commands WR_ML. In this case, the target mode register MR_target corresponding to the second mode register buffer MRBa may not be defined before the host device 10 issues a mode register flush command MRF.

Each of the plurality of management entries MEs may include a plurality of update chase bits. Each of the plurality of update chase bits included in one management entry ME may indicate the state of a bit stored in a buffer bit field BBF of a mode register buffer MRB corresponding to the management entry ME. More specifically, each update chase bit may indicate whether the corresponding buffer bit field BBF and the register bit field RBF are synchronized.

For example, the first management entry ME1 may include a first plurality of update chase bits. The first plurality of update chase bits may indicate whether the raw data of the target mode register MR_target has been updated after being loaded into each buffer bit field BBF of the first mode register buffer MRBa. More specifically, after the raw data provided from the first mode register MRa is loaded into the buffer bit fields BBF of the first mode register buffer MRBa, the host device 10 may update the third and fourth buffer bit fields BBF3 and BBF4 of the first mode register buffer MRBa by issuing a multi-location write command WR_ML. In this case, the command issuance scheduler 11 may change the third bit and the fourth bit of the first plurality of update chase bits to ‘1’. The command issuance scheduler 11 may also manage the update chase bits included in other management entries ME in a similar manner. The command issuance scheduler 11 may determine the type and order of commands to be issued, based on the plurality of update chase bits.

For example, the command issuance scheduler 11 may identify that a bit stored in a specific buffer bit field BBF has been updated, based on the mode register buffer management table MT_MRB. In this case, to read a bit value of the register bit field RBF, the command issuance scheduler 11 may issue a multi-location read command RD_ML after issuing the mode register load command MRL, instead of issuing only the multi-location read command RD_ML for the corresponding buffer bit field RBF. However, the scope of the present disclosure is not limited thereto.

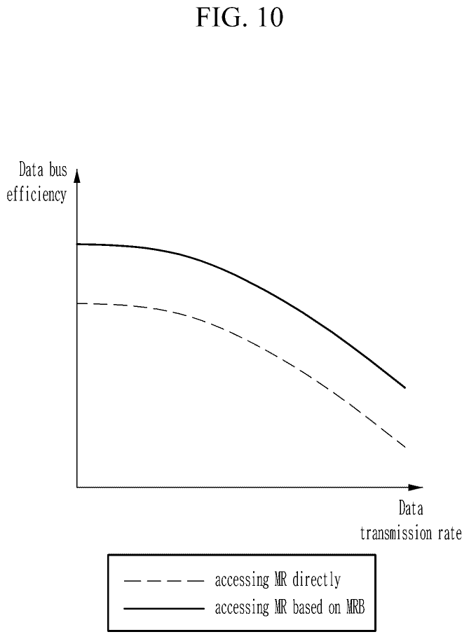

FIG. 10 is a graph illustrating the effect of accessing the mode register according to an embodiment of the present disclosure. Hereinafter, for more concise description, it is assumed that the host device 10 repeatedly accesses data stored in the mode register array 150, with reference to FIGS. 1 to 10. However, the scope of the present disclosure is not limited thereto.

The horizontal axis of FIG. 10 may represent a data transmission rate between the memory device 100 and the host device 10. The vertical axis of FIG. 10 may represent the data bus efficiency. In other words, the vertical axis of FIG. 10 may represent a ratio of a time during which the data bus transmits data to the total operating time of the memory device 100.

The data bus efficiency when the host device 10 directly accesses the mode register MR is illustrated by a dotted line. The data bus efficiency when the host device 10 accesses the mode register MR based on the mode register buffer MRB is illustrated by a solid line.

Referring to the graph indicated by the dotted line, the host device 10 may directly access the mode register MR by issuing a mode register read command MRR. The memory device 100 may transmit bits included in the target mode register MR_target in a form of data signals DQ in response to the mode register read command MRR. In this case, while the memory device 100 transmits the bits included in the target mode register MR_target, the host device 10 may not be able to access the memory bank 140. That is, the data bus between the memory device 100 and the host device 10 may be occupied for a predetermined time to transmit only the bits included in the target mode register MR_target.

On the other hand, referring to the graph indicated by the solid line graph, the host device 10 may indirectly access the mode register MR based on the mode register buffer MRB. For example, the host device 10 may issue a mode register load command MRL to load bits included in the target mode register MR_target into the target mode register buffer MRB_target. Thereafter, the host device 10 may issue a multi-location read command RD_ML to read the bits of the target mode register MR_target from the target mode register buffer MRB_target. In this case, bits stored in the target mode register buffer MRB_target may be transmitted to the host device 10 even while the host device 10 accesses the memory bank 140. Accordingly, according to an embodiment of the present invention, the efficiency of the data bus between the memory device 100 and the host device 10 may be improved. In other words, according to an embodiment of the present invention, a phenomenon in which the efficiency of the data bus is reduced due to access to the mode register MR may be minimized.

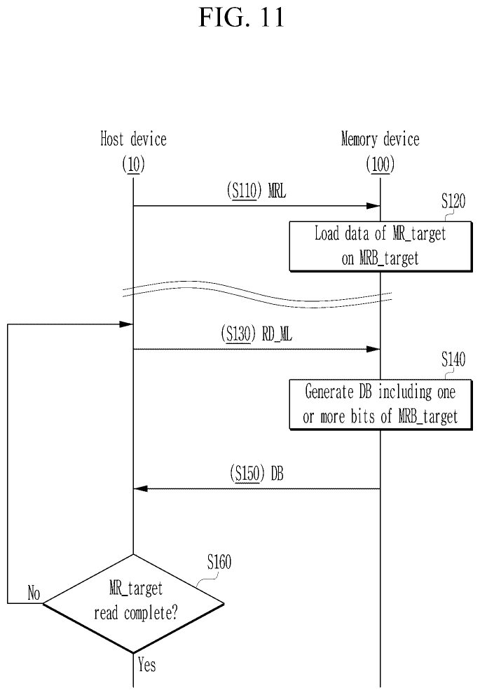

FIG. 11 is a flowchart illustrating the operation of the memory system according to an embodiment. Referring to FIGS. 1 to 11, in operation S110, the host device 10 may transmit a mode register load command MRL to the memory device 100. In this case, the mode register load command MRL may include a mode register address MA indicating a target mode register MR_target.

In an embodiment, when two or more mode register buffers MRB are included in the mode register buffer array 160, the mode register load command MRL may further include a mode register buffer identifier ID_MRB indicating the target mode register buffer MRB_target.

In an embodiment, the host device 10 may update a management entry ME for the target mode register buffer MRB_target corresponding to the mode register load command MRL. For example, the host device 10 may update a management entry ME for the target mode register buffer MRB_target based on the mode register address MA indicating the target mode register MR_target for the target mode.

In operation S120, the memory device 100 may load data of the target mode register MR_target into the target mode register buffer MRB_target. For example, the memory device 100 may update each buffer bit field BBF of the target mode register buffer MRB_target based on raw data provided from the target mode register MR_target.

In operation S130, the host device 10 may transmit the multi-location read command RD_ML to the memory device 100. In this case, the multi-location read command RD_ML may include a bank address and a column address for reading the bank data D_BNK, and may include a target field offset OFST_TF for reading the mode register data D_MR.

In an embodiment, when two or more mode register buffers MRB are included in the mode register buffer array 160, the multi-location read command RD_ML may further include a mode register buffer identifier ID_MRB indicating the target mode register buffer MRB_target.

In operation S140, the memory device 100 may generate a data bundle DB including one or more bits stored in the target mode register buffer MRB_target. For example, the input/output circuit 130 may identify the one or more target fields TF included in the target mode register buffer MRB_target based on the target field offset OFST_TF. The input/output circuit 130 may generate a data bundle DB including bits stored in one or more target fields TF.

In an embodiment, the data bundle DB may include main data DATA_main and auxiliary data DATA_aux. In this case, the main data DATA_main may include bank data D_BNK provided from the memory bank 140. The auxiliary data DATA_aux may include bits read from the target fields TF (i.e., mode register data D_MR).

In operation S150, the memory device 100 may provide the data bundle DB to the host device 10. For example, the input/output circuit 130 may provide the data bundle DB to the host device 10 through a data channel. In this case, the host device 10 may identify the bits stored in the target mode register MR_target based on the data bundle DB.

In operation S160, the host device 10 may determine whether the read operation to the target mode register MR_target has been completed. For example, the command issuance scheduler 11 may determine whether all bits to be read from the target mode register MR_target have been read completely. When it is determined that the read operation to the target mode register MR_target has been completed, the operation of the memory system MS may be terminated. When it is determined that the read operation to the target mode register MR_target has not been completed, operation S130 described above may be repeatedly performed. In this way, the host device 10 may repeatedly issue the multi-location read command RD_ML to read bits stored in the target mode register MR_target. In this case, even when the host device 10 accesses the target mode register MR_target, the efficiency of the data bus may not be degraded.

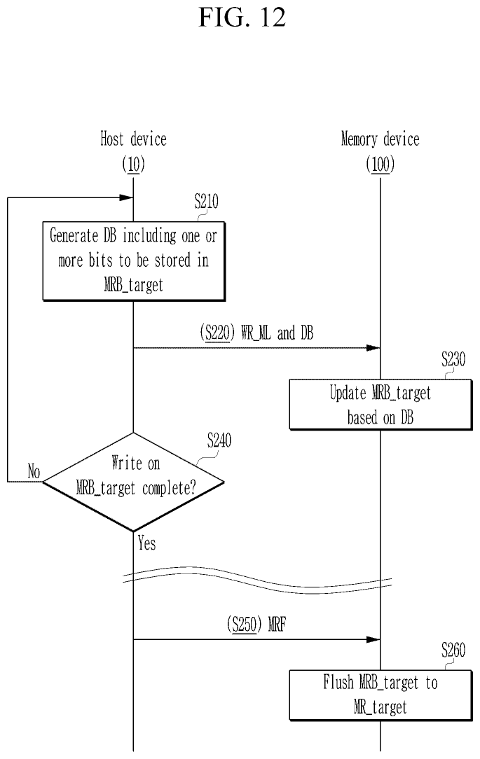

FIG. 12 is a flowchart illustrating the operation of the memory system according to an embodiment. Referring to FIGS. 1 to 10 and 12, in operation S210, the host device 10 may generate a data bundle DB including one or more bits (e.g., mode register data D_MR) to be stored in a target mode register MR_target.

In an embodiment, the data bundle DB may include main data DATA_main and auxiliary data DATA_aux. In this case, the main data DATA_main may include bank data D_BNK to be written in the memory bank 140. The auxiliary data DATA_aux may include bits (i.e., mode register data D_MR) to be stored in the mode register buffer MRB.

In operation S220, the host device 10 may provide the data bundle DB and the multi-location write command WR_ML to the memory device 100. The memory device 100 may receive the data bundle DB based on the multi-location write command WR_ML.

The multi-location write command WR_ML may include a bank address and a column address for writing the bank data D_BNK, and may include a target field offset OFST_TF indicating the target field TF to write the mode register data D_MR.

In an embodiment, when two or more mode register buffers MRB are included in the mode register buffer array 160, the multi-location write command WR_ML may further include a mode register buffer identifier ID_MRB indicating the target mode register buffer MRB_target.

In operation S230, the memory device 100 may update the target mode register buffer MRB_target based on the data bundle DB. For example, the input/output circuit 130 may generate bank data D_BNK and mode register data D_MR based on the data bundle DB. The input/output circuit 130 may provide the bank data D_BNK to a location in the memory bank 140 corresponding to the bank address and the column address included in the multi-location write command WR_ML. The input/output circuit 130 may update at least one target field TF indicated by the target field offset OFST_TF based on mode register data D_MR.

In operation S240, the host device 10 may determine whether writing to the target mode register buffer MRB_target is completed. For example, the command issuance scheduler 11 may determine whether all bits to be written to the target mode register MR_target are prepared in the target mode register buffer MRB_target. When it is determined that the writing to the target mode register buffer MRB_target is completed, following operation S250 may be performed. When it is determined that the writing to the target mode register buffer MRB_target is not completed, operation S210 described above may be repeated.

In operation S250, the host device 10 may provide a mode register flush command MRF to the memory device 100. The mode register flush command MRF may include a mode register address MA indicating the target mode register MR_target.

In an embodiment, when two or more mode register buffers MRB are included in the mode register buffer array 160, the mode register load command MRL may further include a mode register buffer identifier ID_MRB indicating the target mode register buffer MRB_target.

In operation S260, the memory device 100 may flush the target mode register buffer MRB_target to the target mode register MR_target. For example, the memory device 100 may synchronize the target mode register MR_target with the target mode register buffer MRB_target. More specifically, the memory device 100 may update the register bit fields RBF of the target mode register MR_target respectively based on the buffer bit fields BBF of the target mode register buffer MRB_target.

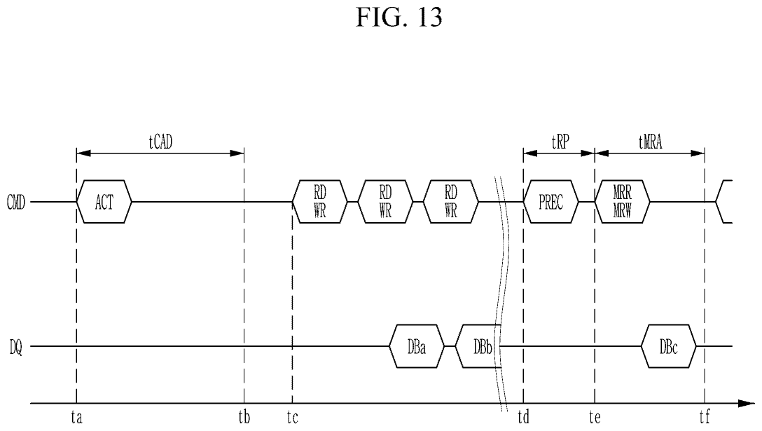

FIG. 13 is a timing diagram illustrating the operation of the memory device according to an embodiment. Referring to FIGS. 1 to 13, the host device 10 may issue an activation command ACT at a first time point ta. From the first time point ta to a second time point tb after the column access delay time tCAD has elapsed, the host device 10 may be prohibited from issuing the read command RD, the multi-location read command RD_ML, the write command WR, and the multi-location write command WR_ML. Since the activation command ACT and the column access delay time tCAD have been previously described with reference to FIG. 5, a detailed description is omitted.

After a third time point tc, the host device 10 may issue a plurality of read commands RD or a plurality of write commands WRs sequentially. The memory device 100 may provide data bundles DB (e.g., first and second data bundles DBa and DBb) to the host device 10 or may receive data bundles DB (e.g., first and second data bundles DBa and DBb) from the host device 10 according to the type of the command CMD provided from the host device 10.

The host device 10 may issue a precharge command PREC at a fourth time point td after the read operation or write operation on the memory device 100 is completed. The memory device 100 may perform a precharge operation on the memory bank corresponding to the precharge command PREC for a row precharge time tRP from a fourth time point td.

The host device 10 may issue a mode register read command MRR or a mode register write command MRW at a fifth time point the after all memory banks 140 are completely precharged. The memory device 100 may provide a third data bundle DBc to the host device 10 or may receive a third data bundle DBc from the host device 10 in response to the mode register read command MRR or the mode register write command MRW.

The third data bundle DBc may not include the bank data D_BNK. However, the third data bundle DBc may have the same capacity as those of the first and second data bundles DBa and DBb. In this case, the time (for example, the number of clock cycles) taken for the memory device 100 to transmit each of the first to third data bundles DBa to DBc may be the same. In other words, the capacity of the data bundle DB transmitted between the host device 10 and the memory device 100 may be constant. In this case, although the third data bundle DBc does not include the bank data D_BNK, the data bus may be inefficiently occupied for a long time for transmission of the third data bundle DBc.

On the other hand, as described above with reference to FIGS. 4 to 5, when the read operation for the mode register MR is performed based on the multi-location read command RD_ML according to an embodiment of the present disclosure, the time occupied by the data bus in order to transmit bits read from the mode register MR may be minimized. Accordingly, according to an embodiment of the present disclosure, latency caused by transmission of the mode register data D_MR during an input/output operation of the host device 10 for the memory device 100 may be minimized.

The issuance of the activation command ACT by the host device 10 may be prohibited from the fifth time point the to the sixth time point tf after the mode register access time tMRA has elapsed. The mode register access time tMRA may indicate a time taken for the data read from the mode register MR corresponding to the mode register read command MRR to be provided to the host device 10, or may indicate a time taken for the data provided from the host device 10 to be written to the mode register MR corresponding to the mode register write command MRW. Accordingly, the mode register access time tMRA may vary depending on the length of time required for transmission of the third data bundle DBc.

On the other hand, as described above with reference to FIGS. 6 to 7, according to an embodiment of the present invention, when a write operation for the mode register MR is performed based on the multi-location write command WR_ML and the mode register flush command MRF, the mode register flush command MRF may not require occupying the data bus. For example, between the twentieth time t20 and the twenty-first time t21 of FIG. 7, data is moved only from the mode register buffer MRB to the mode register MR, and data may not be moved through the data bus between the host device 10 and the memory device 100. Accordingly, the mode register buffer flush time tMRBF may be shorter than the mode register access time tMRA. In this case, the host device 10 may access the memory device 100 earlier than the write operation for the mode register MR is completed.

FIG. 14 is a diagram illustrating an exemplary configuration of the third data bundle of FIG. 13. Referring to FIGS. 1 to 14, the host device 10 may issue a mode register read command MRR to read the third data bundle DBc from the memory device 100, or may issue a mode register write command MRW to provide the third data bundle DBc to the memory device 100.

Hereinafter, the difference between the data bundle DB and the third data bundle DBc described above with reference to FIG. 8 will be mainly described.

The third data bundle DBc may include main data DATA_main and auxiliary data DATA_aux. The main data DATA_main may include 2ª bits, and the auxiliary data DATA_aux may include 2b bits.

The main data DATA_main may include mode register data D_MR. That is, the main data DATA_main may include data to be stored in the mode register MR or data read from the mode register MR, and may not include bank data D_BNK.

The capacity of the mode register data D_MR corresponding to the mode register read command MRR or the mode register write command MRW may be less than the capacity of the main data DATA_main. For example, the capacity of the mode register data D_MR may correspond to the capacity (e.g., 8-bit) of one mode register MR. On the other hand, the main data DATA_main may have a relatively large capacity (e.g., 256-bit).

For more concise description, FIG. 14 illustrates an embodiment in which mode register data D_MR corresponding to the mode register read command MRR or the mode register write command MRW is transmitted in a form of main data DATA_main, but the scope of the present invention is not limited thereto. For example, the host device 10 and the memory device 100 may transmit mode register data D_MR in the form of auxiliary data DATA_aux, similar to that described above with reference to FIGS. 1 to 12.

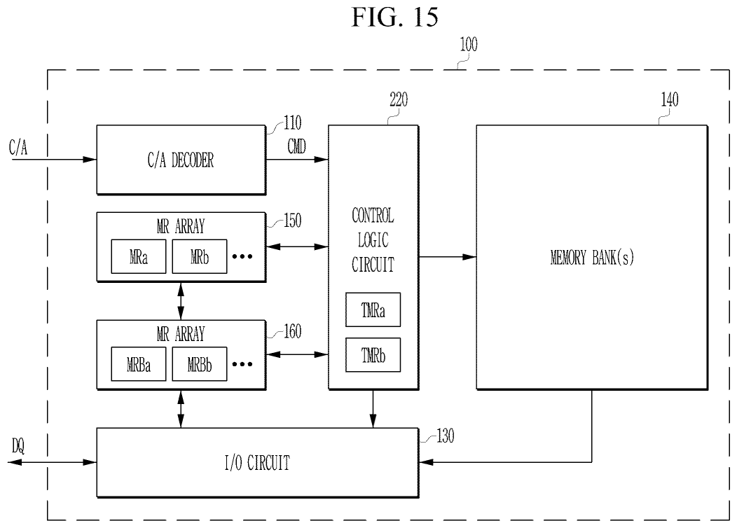

FIG. 15 is a diagram illustrating a configuration of the memory device according to an embodiment. The memory device 100 may include a command/address decoder 110, a control logic circuit 220, one or more memory banks 140, an input/output circuit 130, a mode register array 150, and a mode register buffer array 160. The configuration and operations of the command/address decoder 110, one or more memory banks 140, the input/output circuit 130, the mode register array 150, and the mode register buffer array 160 have been described above with reference to FIG. 2, and thus a detailed description thereof is omitted.

Similar to the control logic circuit 120 described above with reference to FIG. 2, the control logic circuit 220 may control overall operations of the memory device 100.

The control logic circuit 220 may include one or more timers TMR. For example, the control logic circuit 220 may include one or more of the first to second timers TMRa to TMRb.

The control logic circuit 220 may manage the validity of data loaded into the mode register buffer array 160 from the mode register array 150 based on the first timer TMRa. For example, when a excessively long time has elapsed after data has been stored in the specific mode register buffer MRB based on the mode register load command MRL, the control logic circuit 220 may refresh the data stored in the corresponding mode register buffer MRB based on the first timer TMRa.

For a more detailed example, the control logic circuit 220 may measure a time elapsed from the time point when raw data stored in the first mode register MRa is loaded into the first mode register buffer MRBa, based on the first timer TMRa. When the measured time length is longer than a predetermined ‘load valid time’, the control logic circuit 220 may update the first mode register buffer MRBa based on raw data stored in the first mode register MRa.

In this way, the control logic circuit 220 may maintain the data stored in each mode register buffer MRB with newest state based on the first timer TMRa. That is, the control logic circuit 220 may update the data stored in each mode register buffer MRB to the newest state based on the first timer TMRa even when a new mode register load command MRL is not issued from the host device 10. In this case, the host device 10 may read the latest bits of the mode register MR from the mode register buffer MRB by issuing only the multi-location read command RD_ML even when the host device 10 does not issue a new mode register load command MRL.

However, the scope of the present invention is not limited thereto, and when a long time has elapsed after data has been stored in the specific mode register buffer MRB based on the mode register load command MRL, the control logic circuit 220 may invalidate the data stored in the corresponding mode register buffer MRB based on the first timer TMRa. For example, the control logic circuit 220 may invalidate the bits stored in the first mode register buffer MRBa when the length of time measured by the first timer TMRa is longer than a predetermined load valid time.

In an embodiment, the control logic circuit 220 may be implemented to update (e.g., refresh or invalidate) only the mode register buffer MRB loaded with data for the mode register MR indicating the state of the memory device 100 (e.g., temperature, operating voltage, whether a row hammering threat has occurred, whether an additional refresh operation is required, etc.) based on the first timer TMRa. For example, the control logic circuit 220 may be implemented to update the mode register buffer MRB loaded with data for the mode register MR used to determine the operation of the memory device 100 only in response to the mode register load command MRL (i.e., not update based on the first timer TMRa). However, the scope of the present disclosure is not limited thereto.

The control logic circuit 220 may manage data stored in the mode register buffer MRB based on the second timer TMRb. For example, the control logic circuit 220 may measure the time elapsed after the last multi-location write command WR_ML for a specific mode register buffer MRB has been received, based on the second timer TMRb. When the measured time is longer than a threshold time length, the control logic circuit 220 may invalidate the corresponding mode register buffer MRB. However, the scope of the present invention is not limited thereto, and the control logic circuit 220 may store the data of the corresponding mode register buffer MRB in any mode register MR determined in advance.

In an embodiment, the memory device 100 may update only valid bits stored in the target mode register buffer MRB to the corresponding register bit field RBF in response to the mode register flush command MRF. However, the scope of the present disclosure is not limited thereto.

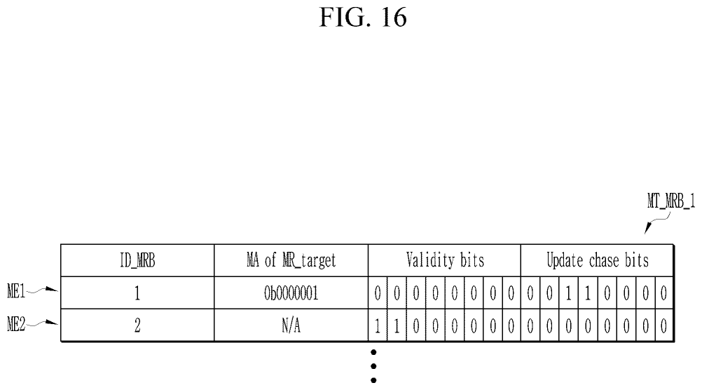

FIG. 16 is a diagram illustrating an exemplary configuration of the mode register buffer management table of FIG. 1 according to an embodiment. Referring to FIGS. 1 to 16, the mode register buffer management table MT_MRB of FIG. 1 may be implemented as a mode register buffer management table MT_MRB_1. Hereinafter, differences between the mode register buffer management table MT_MRB and the mode register buffer management table MT_MRB_1 will be described.

The command issuance scheduler 11 may manage the state of each mode register buffer MRB based on the mode register buffer management table MT_MRB_1.

The mode register buffer management table MT_MRB may include a plurality of management entries ME. Each of the plurality of management entries ME may include a mode register address MA for a corresponding target mode register MR_target. Each of the plurality of management entries MEs may include a plurality of update chase bits.

Each of the plurality of management entries ME may include a plurality of validity bits. Each of the plurality of validity bits included in one management entry ME may indicate the validity of a bit stored in a buffer bit field BBF corresponding to the management entry ME. That is, each validity bit may indicate whether a bit stored in the corresponding buffer bit field BBF is valid.

The first management entry ME1 may include a first plurality of validity bits. A first plurality of validity bits may indicate validity of different buffer bit fields BBF included in the first mode register buffer MRBa. For example, the first plurality of validity bits may indicate whether a bit stored in the corresponding buffer bit field BBF has been invalidated by the memory device 100 (e.g., in a manner based on the timer TMR of FIG. 15).

For a more detailed example, when a threshold time length has elapsed after the raw data provided from the first mode register MRa has been loaded into the buffer bit fields BBF of the first mode register buffer MRBa, the command issuance scheduler 11 may change each of the first plurality of valid bits to ‘0 (e.g., invalid)’.

Similarly, the second management entry ME2 may include a second plurality of validity bits. The second plurality of validity bits may indicate validity of different buffer bit fields BBF included in the second mode register buffer MRBb.

For a more detailed example, the host device 10 may issue one or more multi-location write commands WR_ML to update the first and second buffer bit fields BBF1 and BBF2 of the second mode register buffer MRBb. In this case, the command issuance scheduler 11 may change the first bit and the second bit of the second plurality of valid bits to ‘1 (valid)’.

In this way, the command issuance scheduler 11 may manage validity bits included in another management entry ME.

The command issuance scheduler 11 may determine the type and order of commands to be issued, based on a plurality of validity bits. For example, the command issuance scheduler 11 may identify that a bit stored in a specific buffer bit field BBF is invalid, based on the mode register buffer management table MT_MRB_1. In this case, the command issuance scheduler 11 may issue a multi-location read command RD_ML after issuing the mode register load command MRL to refresh the corresponding buffer bit field BBF. However, the scope of the present disclosure is not limited thereto.

The above are the specific embodiments for implementing the present disclosure. The present disclosure may include not only the embodiments described above, but also embodiments that are simply redesigned or may be easily modified. The present disclosure will also include techniques that may be easily modified and practiced by using the embodiments. Accordingly, the scope of the present disclosure should not be limited to the above-described embodiments, but should be defined by the following patent claims as well as those equivalents of the claims of the present disclosure.

What is claimed is:

1. A memory device communicating with a host device, the memory device comprising:
a plurality of memory banks;
a mode register array including a plurality of mode registers;
a first mode register buffer, including a first plurality of buffer bit fields, configured to load raw data provided from a target mode register, which is one of the plurality of mode registers, to the first plurality of buffer bit fields in response to a first command received from the host device; and
an input/output circuit configured to output one or more target bits stored in the first plurality of buffer bit fields to the host device in response to a second command received from the host device.

2. The memory device of claim 1, wherein:
the memory device is configured to receive the first command independently with a state of each of the plurality of memory banks.

3. The memory device of claim 1, wherein:
a number of the plurality of buffer bit fields included in the first mode register buffer corresponds to a capacity of each of the plurality of mode registers.

4. The memory device of claim 1, wherein the input/output circuit is configured to:
identify one or more target bit fields, which are some of the first plurality of buffer bit fields, based on a target field offset included in the second command; and
determine bits stored in the one or more target bit fields as the one or more target bits.

5. The memory device of claim 1, wherein:
the input/output circuit is configured to output a data bundle to the host device in response to the second command, and
the data bundle includes:
a main data including a bank data provided from the plurality of memory banks; and
an auxiliary data including the one or more target bits.

6. The memory device of claim 5, wherein:
the second command includes an address for one of the plurality of memory banks; and
the bank data is a data read from the plurality of memory banks based on the address.

7. The memory device of claim 5, wherein:
a capacity of the bank data is 2^{a} bits, where ‘a’ is an integer greater than 0, and
a capacity of the auxiliary data is 2^{b} bits, where ‘b’ is an integer greater than 0 and less than ‘a’.

8. The memory device of claim 1, further configured to receive the second command from the host device after a second time point at which a mode register buffer load time has elapsed from a first time point at which the first command is received.

9. The memory device of claim 1, wherein the one or more target bits indicate state information of the memory device.

10. The memory device of claim 1, further comprising a control logic circuit configured to:
update the first plurality of buffer bit fields based on the target mode register, after a predetermined load valid time has elapsed from a time point when the raw data is loaded to the first plurality of buffer bit fields.

11. The memory device of claim 1, further comprising a second mode register buffer including a second plurality of buffer bit fields,
wherein the first command and the second command include a mode register buffer identifier for the first mode register buffer.

12. A memory system comprising:
a memory device including:
a mode register buffer including a plurality of buffer bit fields and a mode register array including a plurality of mode registers; and
a host device configure to:
load, into the plurality of buffer bit fields, a raw data stored in a first target mode register, which is one of the plurality of mode registers, by issuing a first command; and
read at least a part of the plurality of buffer bit fields by issuing a second command.

13. The memory system of claim 12, wherein:
the host device is configured to store a mode register buffer management table indicating a state of each of bits stored in the plurality of buffer bit fields.

14. The memory system of claim 13, wherein the mode register buffer management table includes:
a mode register address for the first target mode register; and
a plurality of update chase bits respectively indicating whether the plurality of buffer bit fields have been updated after the raw data is loaded into the plurality of buffer bit fields.

15. The memory system of claim 12, wherein the host device is configured to issue the first command independently with a state of each of a plurality of memory banks included in the memory device.

16. The memory system of claim 12, wherein:
the memory device further includes a plurality of memory banks; and
in response to the second command, the memory device is configured to output, to the host device, a bank data provided from the plurality of memory banks and a mode register data including target bits stored in the at least a part of the plurality of buffer bit fields.

17. The memory system of claim 12, wherein the host device is further configured to:
update some of the plurality of buffer bit fields by issuing a third command, and;
update a second target mode register, which is one of the plurality of mode registers, based on the mode register buffer by issuing a fourth command.

18. The memory system of claim 17, wherein:
the host device is configured to issue the fourth command after all memory banks included in the memory device are precharged.

19. A memory device comprising:
a plurality of memory banks;
a mode register array including a plurality of mode registers;
an input/output circuit configured to communicate with an external device; and
a mode register buffer, connected between the mode register array and the input/output circuit, configured to buffer input/output for one of the plurality of mode registers.

20. The memory device of claim 19, wherein:
the input/output circuit is configured to communicate with the external device in a unit of memory bundle which includes a mode register data for the mode register buffer and a bank data for the plurality of memory banks.
